(19) United States
(12) Patent Application Publication
(10) Pub. No.: US 2004/0118679 A1
(43) Pub. Date: Jun. 24, 2004

(54) Target and manufacturing method thereof

(76) Inventors: Shigeru Taniguchi, Yasugi-shi (JP); Katsunori Iwasaki, Yasugi-shi (JP)

Correspondence Address: J.C. Patents, Inc., Suite 250, 4 Venture, Irvine, CA, 92618, US

(21) Appl. No.: 10/626,237

(22) Filed: Jul. 23, 2003

(30) Foreign Application Priority Data
Jul. 25, 2002 (JP) 2002-216295

(51) Int. Cl. C23C 14/34; B23K 20/18; B23K 1/20; B23K 31/02

(52) U.S. Cl. 204/298.12; 204/298.13; 228/194; 228/118; 228/122.1

(57) ABSTRACT

A sputtering target is provided, including a target material and a backing plate that are bonded with a strong adhesion at a reduced cost. The method for bonding the target material and the backing plate does not use a special soldering material, and is therefore cheaper and more reliable. The target includes an inorganic target material and a backing plate that are bonded with a soldering material between them. At least one of the target material and the backing plate is coated with a coupling agent of a semi-metal oxide or a metal oxide.

### CROSS-REFERENCE TO RELATED APPLICATION

This application claims the priority benefit of Japanese application serial no. 2002-216295, filed Jul. 25, 2002.

### BACKGROUND OF THE INVENTION

1. Field of the Invention

The present invention relates to a target including a backing plate and a method for manufacturing the same. The target is used as a depositing source in, for example, a sputtering process.

2. Description of the Related Art

In a target used in a deposition process, such as a sputtering process or the like, the target material is usually attached to a backing plate formed from a metallic material like copper to allow the target to cool down more rapidly or to be installed in an apparatus more easily. Moreover, the soldering material used in a target is usually indium (In) that has a low melting point.

Although there are various target materials currently being used in the art, directly wetting a target material with a soldering material is difficult in most case. Therefore, in the prior art, the surface of a target material to be applied with a soldering material is metallized in advance by forming a metal film of copper, nickel or the like with electroplating or vacuum deposition, so as to enhance the wettability of the target material with the soldering material. The soldering material is then applied to the target material. Moreover, gold can be added into a soldering material of indium to enhance the wettability of the target material with the soldering material, as described in, for example, JP-A-08-269703.

However, when the bonding surface of the target material is metallized to enhance the wettability of the target material with the soldering material, the adhesion between the metallized layer and the target material may not be sufficient, and an additional cost is required for forming the metallized layer. Moreover, since the soldering material of indium containing gold for enhancing the wettability is expensive, the cost of manufacturing the target is increased. The cost of bonding the target material and the backing plate and the adhesion between the two both are very important issues in the manufacture of a sputtering target.

### SUMMARY OF THE INVENTION

In view of the foregoing, one object of this invention is to provide a sputtering target that allows the use of an inexpensive and reliable method for bonding the target material and the backing plate.

The inventors have studied to improve the adhesion between the target material and the backing plate, and provided a new type of target that has a remarkably higher adhesion strength. In the manufacturing of the target, a coupling agent of a semi-metal oxide or a metal oxide is coated on the bonding surface of the target material or the backing plate before a molten soldering material is applied to the same.

The target of this invention includes an inorganic target material and a backing plate that are bonded with a soldering material between them. At least one of the target material and the backing plate is coated with a coupling agent of a semi-metal oxide or a metal oxide.

The target of this invention can be manufactured with, for example, the method disclosed in this invention. In the method, a coupling agent of a semi-metal oxide or a metal oxide is coated on the bonding surface of at least one of the target material and the backing plate, and then a molten soldering material is disposed on the bonding surface of at least one of the target material and the backing plate. Thereafter, the target material and the backing plate are bonded via the soldering material.

The coupling agent constituting the coupling layer of this invention is preferably a commercially available agent that can be easily obtained, and is suitably a silane coupling agent or one composed of an oxide of a IVa-group element in the Periodic Table of Elements, such as titanium (Ti) or zirconium (Zr). The silane coupling agent is particularly suitable in consideration of the facilitation of handling and the cost.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 schematically illustrates a cross-sectional view of the target of Sample 1 according to a preferred embodiment of this invention.

FIG. 2 illustrates an exemplary procedure of the target bonding method of this invention.

### DESCRIPTION OF THE PREFERRED EMBODIMENTS

One important feature of this invention is the formation of a coupling layer of a semi-metal oxide or a metal oxide. The semi-metal oxide or metal oxide coupling agent can be an oxide of a IVa-group element in the Periodic Table of Elements, typically titanium (Ti) or zirconium (Zr), or an oxide of a semi-metal like aluminum (Al) or silicon, particularly a silane coupling agent. The silane coupling agent that is used most widely is synthesized via a polycondensation reaction, wherein silicon atoms form bridging structures via oxygen bonding. Generally, an oxide-type coupling agent has a hydrolyzable group and an organic functional group bonded to a metal atom or a semi-metal atom like a silicon atom, and such a coupling agent is used to bond a metal and an organic substance.

In this invention, a strong adhesion between inorganic materials is possible via the use of the coupling agent, which may be attributed to the effect of the hydrolyzable group to the inorganic materials having poor wettability. Accordingly, when the metal atom or the semi-metal atom of a coupling agent is bonded with a hydrolyzable group, a higher bonding strength can be anticipated. Moreover, a molten soldering material directly contacts with the coated coupling agent in this invention. The bonded body obtained through such a special mode can have a good bonding strength, which is a main feature of this invention.

Typically, in this invention, the coupling agent is coated on the bonding surface of the target material having poor wettability to enhance the bonding strength of the soldering material. Of course, if the material of the backing plate has poor wettability, the coupling agent can be coated on the backing plate or on both of the target material and the backing plate. That is, the coupling agent of a semi-metal oxide or a metal oxide is coated on the bonding surface of at least one of the target material and the backing plate according to the properties of the two. In this step, the coupling agent is preferably coated uniformly on the whole bonding surface of the target material or the backing plate.

After the coupling agent is coated, a molten soldering material is disposed on the bonding surface of at least one of the target material or the backing plate, and then the target material or the backing plate are bonded. In this step, the soldering material is preferably disposed on both of the target material and the backing plate for bonding them, since the soldering material merges well in such a manner. With the aforementioned steps, a target of this invention is obtained with a coupling layer of a semi-metal oxide or a metal oxide formed on at least one of the target material and the backing plate.

Since this invention uses the aforementioned coupling agent to bond the target material and the backing plate, no metallized layer is required to enhance the wettability of the target material and/or the backing plate with the soldering material, and the process (e.g., a vacuum deposition process) for forming a metallized layer can be omitted.

Moreover, the preferable examples of the soldering material used to bond the target material and the backing plate include indium (In), indium alloys, tin (Sn) and tin alloys that have low melting points and good softness.

### EXAMPLES

The specific examples of this invention are described as follows to further explain the contents of this invention. The examples are not intended to restrict the scope of this invention, and this invention covers any variations of the examples provided they fall within the principles of this invention.

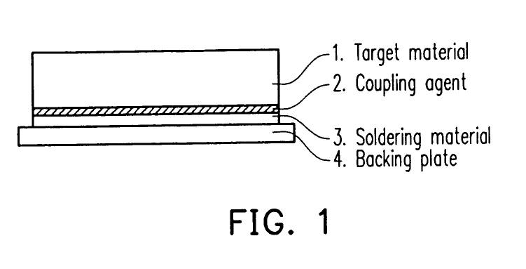

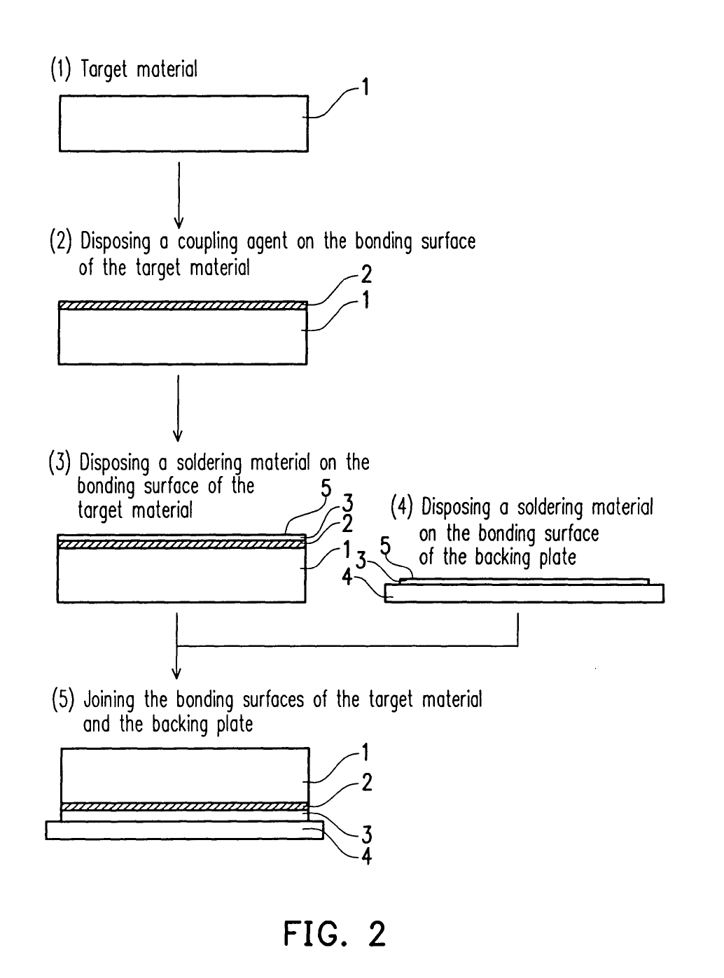

The target materials of various compositions and sizes, the copper backing plates and the coupling agents as described in Table 1 are prepared. The method for fabricating Samples 1-7 of the examples of this invention is described first. To fabricate a sample (1, 2, . . . , or 7), a silane coupling agent APZ-6633 produced by Nippon Unicar Co., Ltd. is coated on the bonding surface of a target material, and then a molten soldering material is disposed on the target material and heated to 160° C. or above to wet the surface of the target material. The molten soldering material is also disposed on the backing plate and heated to 160° C. or above to wet the surface of the backing plate, and then the bonding surfaces of the target material and the backing plate are joined together. The aforementioned steps for joining the bonding surfaces 5 of a target material 1 and a backing plate 4 using a soldering material 3 with an intermediate coupling agent 2 are sequentially illustrated in FIG. 2. Moreover, a cross-sectional view of the target formed with the above-mentioned bonding method is schematically illustrated in FIG. 1.

The method for fabricating Samples 8-9 is described as follows. A titanate coupling agent Orgatics TA-25 (Sample 8) or a zirconium coupling agent Orgatics ZA-60 (Sample 9) produced by Matsumoto Chemical Industry Co., Ltd. are coated on the bonding surface of a target material, and then a molten soldering material is disposed on the target material and heated to 160° C. or above to wet the surface of the target material. The molten soldering material is also disposed on the backing plate and heated to 160° C. or above to wet the surface of the backing plate, and then the two bonding surfaces are joined.

Moreover, to fabricate Sample 10 of the comparative example, a metallized layer of copper is formed on a target material of pure molybdenum (Mo) with electroplating, and then a molten soldering material is disposed on the target material and heated to 160° C. or above to wet the surface of the target material. The target material is then bonded with a backing plate disposed with the same soldering material. In the fabrication of Sample 11, a soldering material is directly coated on the bonding surface of a target material of pure molybdenum (Mo) and heated to 160° C. or above, wherein no surface treatment like metallized layer formation has been performed to the bonding surface. Since the wettability of the target material with the soldering material is not enhanced, the target material cannot be bonded with the backing plate.

After the target Samples 1-10 manufactured as above cool down, an ultrasonic flaw detector produced by Hitachi Construction Machinery Co., Ltd. is used to measure the bonding area ratios of the target samples. Moreover, to measure the bonding strength of the target material and the backing plate, test plates are prepared from the samples and are drawn vertically along the direction of thickness using a drawing tester for measuring the drawing strength of the target. The drawing strength and the bonding area ratio of each sample are listed in Table 1, wherein the drawing strength of a sample indicates the bonding strength of the same. Moreover, the bonding strength and the bonding area ratio of Sample 11 cannot be measured since the target material and the backing plate thereof cannot be bonded together.

TABLE 1

| | Target material | | | | | Bonding | Bonding | |
|---|---|---|---|---|---|---|---|---|
| Sample | Composition | | Soldering | Structure of sputtering | | strength | area ratio | |
| No. | (at %) | Size (mm) | material | target | Coupling agent | (N/cm²) | (%) | Note |
| 1 | pure Mo | 8 × 980 × 1150 | In | Target material + | Silane coupling | 11.5 | 99.2 | Example of this |
| | | | | Soldering material + | agent | | | invention |
| | | | | Backing plate | | | | |
| 2 | pure Cr | 6 × 980 × 1150 | In | Target material + | Silane coupling | 11.8 | 99.1 | Example of this |
| | | | | Soldering material + | agent | | | invention |
| | | | | Backing plate | | | | |
| 3 | 65Mo-35W | 16 × 924 × 1134 | In | Target material + | Silane coupling | 12.0 | 99.2 | Example of this |
| | | | | Soldering material + | agent | | | invention |
| | | | | Backing plate | | | | |
| 4 | 97Al-3Ti | 10 × 630 × 710 | In | Target material + | Silane coupling | 11.7 | 98.9 | Example of this |
| | | | | Soldering material + | agent | | | invention |
| | | | | Backing plate | | | | |
| 5 | 80Si-20Mo | φ 216 × 6 | In | Target material + | Silane coupling | 12.1 | 99.2 | Example of this |
| | | | | Soldering material + | agent | | | invention |
| | | | | Backing plate | | | | |
| 6 | 90W-10Ti | φ 314 × 6 | In | Target material + | Silane coupling | 12.2 | 99.3 | Example of this |
| | | | | Soldering material + | agent | | | invention |
| | | | | Backing plate | | | | |
| 7 | pure Ti | φ 293 × 6 | In | Target material + | Silane coupling | 11.5 | 98.8 | Example of this |
| | | | | Soldering material + | agent | | | invention |
| | | | | Backing plate | | | | |
| 8 | pure Mo | 8 × 980 × 1150 | In | Target material + | Titanate | 11.8 | 99.8 | Example of this |
| | | | | Soldering material + | coupling agent | | | invention |
| | | | | Backing plate | | | | |
| 9 | pure Mo | 8 × 980 × 1150 | In | Target material + | Zirconium | 11.2 | 99.3 | Example of this |
| | | | | Soldering material + | coupling agent | | | invention |
| | | | | Backing plate | | | | |
| 10 | pure Mo | 8 × 980 × 1150 | In | Target material + | No coupling | 11.8 | 98.9 | Comparative |
| | | | | Metallized layer + | agent | | | example |
| | | | | Soldering material + | | | | |
| | | | | Backing plate | | | | |
| 11 | pure Mo | 8 × 980 × 1150 | In | Target material + | No coupling | NA | NA | Comparative |
| | | | | Soldering material + | agent | | | example |
| | | | | Backing plate | | | | |

As shown in Table 1, each of the sputtering targets of Samples 1-9 of this invention, on which a silane coupling agent or a metal oxide coupling agent is coated instead of a metallized layer, has a bonding strength higher than 11.2 N/cm² and a bonding area ratio higher than 98.8%. The bonding strengths of Samples 1-9 are at the same level as or even higher than that of Sample 10 in which a metallized layer is formed.

Since the wettability of the target material and the backing plate with the soldering material can be remarkably improved in this invention, the bonding strength between the target material and the backing plate can be easily enhanced. Therefore, the technique disclosed in this invention is indispensable for the manufacture of targets with backing plates.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A target, comprising an inorganic target material and a backing plate bonded with a soldering material between them, wherein at least one of the target material and the backing plate is coated with a coupling agent of a semi-metal oxide or a metal oxide.

2. The target of claim 1, wherein the coupling agent comprises an oxide of an IVa-group element in the Periodic Table of Elements.

3. The target of claim 1, wherein the coupling agent comprises a silane coupling agent.

4. A method for manufacturing a target by bonding an inorganic target material and a backing plate with a soldering material between them, comprising:
coating a coupling agent of a semi-metal oxide or a metal oxide on a bonding surface of at least one of the target material and the backing plate;
disposing a molten soldering material on the bonding surface of at least one of the target material and the backing plate; and
bonding the target material and the backing plate via the soldering material.

5. The method of claim 4, wherein the coupling agent comprises an oxide of an IVa-group element in the Periodic Table of Elements.

6. The method of claim 4, wherein the coupling agent comprises a silane coupling agent.
